(19) United States
(12) Patent Application Publication
(10) Pub. No.: US 2025/0210332 A1
(43) Pub. Date: Jun. 26, 2025

(54) SHUTTER SYSTEM FOR GAP-FREE SHIELDING OF A COATING SOURCE, AND ASSOCIATED METHOD

(71) Applicant: FHR ANLAGENBAU GMBH, Ottendorf-Okrilla (DE)

(72) Inventors: Sven HAEBERLEIN, Ottendorf-Okrilla (DE); Marcus SCHUELER, Freital (DE); Peggy KLUGE, Lichtenberg (DE); Gregor HESSE, Langebrück (DE)

(73) Assignee: FHR ANLAGENBAU GMBH, Ottendorf-Okrilla (DE)

(21) Appl. No.: 18/849,323

(22) PCT Filed: Feb. 22, 2023
(86) PCT No.: PCT/EP2023/054345

§ 371 Date: Sep. 20, 2024

(30) Foreign Application Priority Data
Mar. 21, 2022 (DE) 10 2022 106 546.4
Nov. 3, 2022 (DE) 10 2022 129 012.3

(51) Int. Cl. H01J 37/34; C23C 14/24; C23C 14/30; C23C 14/34; H01J 37/04

(52) U.S. Cl. CPC H01J 37/3447; C23C 14/24; C23C 14/30; C23C 14/34; H01J 37/045; H01J 2237/332

(57) ABSTRACT

The invention discloses a shutter system consisting of a shutter for shielding a coating source in a vacuum system, wherein the shutter is configured such that it can be slid in front of the costing source; and a method which is carried out by means of the shuner system according to the invention. The problem of the invention of specifying an arrangement for a shutter system, by means of which the coating source can be optimally shielded, in order to completely prevent both cross-contaminations and undesired coatings on a substrate to be coated, is solved by a shutter system in which the shuner can be positioned above the coating source by means of a rotary and/or pivoting and/or folding/tilting movement, and the shutter is configured to carry out an additional relative movement with respect to the coating source, and/or the coating source is configured to carry out an additional relative movement with respect to the shatter, wherein the shutter covers the coating source in a scaling and gap-free manner.

The invention relates to a shutter system consisting of a shutter for shielding a coating source in a vacuum system, wherein the shutter is designed to be movable in front of the coating source.

The invention likewise relates to a method which is conducted with the aid of the shutter system of the invention.

Sputtering is a coating technique from the group of PVD (physical vapor deposition) methods. Sputtering, also called cathodic atomization, means a physical operation in which atoms are removed from a solid-state body, called the target, by bombardment with high-energy (noble gas) ions and are converted to the gas phase. Depending on the materials used and the layer properties and deposition rates envisaged, various sputtering methodologies are used.

In the field of coating technology, sputtering accordingly serves to atomize a material which is then deposited on a substrate and forms a solid layer. In order to achieve a defined layer thickness in the coating, especially in the sputtering, of various materials onto a substrate, shutter systems are used in order to control the flow of material onto the substrates to be coated and to protect the target from incorrect coating.

Sputtering takes place in a coating system under vacuum conditions. Depending on the sputtering variant used (DC sputtering, HF sputtering, magnetron sputtering, ion beam sputtering, reactive sputtering, inter alia), a voltage is applied between two electrodes and a working gas is admitted into the gas space. Impact ionization of the atoms of the working gas used, for example argon, forms a plasma in the gas space. The target usually forms the negative electrode, and a process chamber or the substrate to be coated usually forms the positively charged electrode. In the case of magnetron sputtering, there is an additional magnetic field arranged behind the cathode plate. In the case of reactive sputtering, one or more reactive gases are added to the inert working gas (argon). The gases react at the target in the vacuum chamber or at the substrate with the atomized layer atoms and form new materials. In ion beam sputtering, a beam of noble gas ions (argon, krypton, xenon) is directed from an ion source onto the target—this results in atomization by the incident ion beam.

For a stable sputtering process, the coating system is switched on, i.e. the voltage is applied to the electrodes and the plasma is ignited and the desired operating power for a stable process is set and established. Only thereafter is the shutter opened in order to commence the coating of the substrates. The coating source is shielded beforehand by a shutter. In order to assure the ignition of the plasma, a gap of a few millimeters must exist between coating source and shutter. Typically, the shutter is a metal sheet which is pivoted from the side in front of the coating source, such that no material unintentionally reaches the substrates to be coated from the coating source.

Any unwanted flow of material, called cross-contamination, onto the substrate and the environment from the coating source, is most effectively prevented when the distance of the metal sheet from the coating source is very small and hence the coating source is optimally shielded from the substrates.

Especially in the case of assemblies of multiple coating sources within a coating chamber or process chamber, there can be mutual coating of the coating sources (targets) by cross-contamination if the coating sources cannot be completely sealed. As a result, it is often necessary to remove material from the contaminated targets again before the actual process of coating the substrates by sputtering, also called clear-sputtering, in order to maintain and to assure the quality of the coating materials. This results in reduction both of the quality of coating and the exploitation of material, and also of the productivity of the coating assembly.

The shutter sheets used have to date been inserted or pivoted in front of the coating source at a distance of about 1 to 4 mm. However, this distance cannot ensure completely closed shielding of the coating source. But the distance is necessary for the initiation of sputtering of a coating source. Lower, i.e. smaller, distances cannot be implemented in practical execution since these typically lead to friction between the shutter sheet and coating source. These friction effects cause many unwanted particles that can lead to additional contamination of the coated substrates. This usually leads to severe losses of quality of the layer, for example to detachment of the layers from the substrate up to and including production of rejects. WO 2021/091890 A1 discloses a shutter mechanism in which a shutter is connected to an actuator via a coupling system such that the shutter can be moved in a composite movement from an open position to a closed position over a coating Source. The actuator here merely performs a linear movement along a translation axis, with conversion of a linear movement of the shutter to a tilting movement via a curved groove and back to a concluding linear movement until the shutter encloses the sputtering source. The shutter firstly performs a linear movement along the translation axis of the actuator, then a rotary movement, for example by 90°, to the translation axis of the actuator, and finally a linear movement, again along the translation axis of the actuator. A disadvantage is that these movements cannot be controlled separately and independently from one another since, firstly, they are defined by the curved groove and, secondly, fine adjustment of the shutter by means of the actuator is possible only to a very limited degree. Especially in the case of use of a pneumatic actuator, persistence of the shutter in an intermediate position, for example for the initiation of sputtering or pre-sputtering processes, i.e. a few millimeters above the sputtering source, by the solution described in WO 2021/091890 A1, is not possible and reproducible only inaccurately without additional technical devices.

The fact that the axis of rotation of the shutter in the solution described in WO 2021/091890 A1 does not lie parallel to the longitudinal axis of the coating source means that it is also possible during the pivoting of the shutter between open and closed positions for there to be disadvantageous curvature of the gas plasma since there is a change in the angle between target surface and shutter surface. This can additionally result in unwanted coating of the inside of the chamber or the coating source itself.

It is likewise disadvantageous that the actuator in WO 2021/091890 A1 is disposed with the curved groove within the vacuum chamber. The mechanical stress exerted by the coupling system and the associated friction in the curved groove can result in abrasion, which is unwanted in a coating system with high purity demands. Maintenance and/or repair of the shutter actuator is thus also significantly more demanding since this can be effected merely with ventilation of the vacuum chamber.

It is therefore an object of the invention to specify an assembly for a shutter system by means of which the coating source can be optimally shielded, in order to completely prevent both cross-contamination and unwanted coatings on a substrate to be coated. The aim here shall be a compact assembly. The assembly shall be low-maintenance and necessitate a low level of complexity in repair measures.

The shutter system shall be positionable exactly in any required and desired position.

The object is achieved by a shutter system as claimed in independent assembly claim 1. The shutter system consists of a shutter for shielding a coating source in a vacuum system, where the shutter is designed to be movable in front of the coating source. According to the invention, the shutter is positionable over the coating source by means of a rotary and/or pivoting and/or folding/tilting movement and the shutter is designed to perform an additional relative movement to the coating source and/or the coating source is designed to perform an additional relative movement to the shutter, where the shutter covers the coating source in a sealing and gap-free manner.

Sealing and gap-free coverage means complete shielding of the coating source from the rest of the process chamber, such that any cross-contamination to the coating source and any unwanted coatings on the substrate to be coated are prevented.

It is advantageous that the shutter of the shutter system is not just pivoted or rotated or folded or tilted over the coating source in one first degree of freedom, but that the shutter or the coating source are moved in a mutually sealing manner by a relative movement between shutter and coating source in a second degree of freedom. Either the shutter performs a back-and-forth movement in the direction of the coating source or the coating source performs a back-and-forth movement in the direction of the shutter, such that the shutter and the coating source are positioned with sealing, i.e. with complete closure, with respect to one another. In this case, there is no formation of particles by friction between shutter sheet and coating source, as is the case with pure pivoting of the shutter across the coating source. With the shutter closed, there no longer exists any gap, which means that contamination of the target material by operation of other sources in the same arrangement is prevented.

The shutter may be positioned over the coating source, for example, by a rotary movement about an axis or by a pivoting movement via a lateral approach toward the coating source. Only thereafter does the relative movement or pivoting movement proceed between shutter and coating source. Both movements are performable independently, such that the shutter is positionable in any required and desired position. There is no deflection of the gas plasma by the movements of the shutter.

The solution proposed allows a significantly more compact arrangement of different coating sources to take place in a parallel and/or co-coating arrangement (e.g. sputtering arrangement), since cross-contamination of the coating sources is prevented. There is no longer any need for a large projection of the shutter sheets.

In one configuration of the shutter system of the invention, the relative movement between shutter and coating source is implemented by means of bellows or ring seals and/or linear feedthroughs. This reduces mechanical wear within the vacuum chamber to a minimum. There is no occurrence of contamination by abrasion or mechanical friction,

The relative movement between shutter and coating source is effected by means of a back-and-forth movement which is effected either by the shutter or by the coating source. Execution of the relative movement by the shutter system is typically the simpler method owing to the mechanical implementation. Performance of the relative movement by the coating source is an option in the case of shared utilization of a stop by multiple coating sources (for example perforated plates).

In another configuration of the shutter system of the invention, a distance between coating source and shutter is formed in an adjustable manner. This has the advantage that, at the start of the process, for ignition of the plasma in the sputtering operation, the necessary gap between coating source and shutter can be established and, in the actual coating process, in particular with multiple coating sources, the respective coating source can be optimally sealingly shielded. This is possible by virtue of the separately controllable and independently executable movements of the shutter system.

Shielding is further optimized when, in a further configuration of the shutter system of the invention, the shutter has a folded-over edge. By virtue of the folded-over edge, the shutter acts like a kind of hood over the coating source, such that cross-contamination can be completely prevented.

In a further configuration of the shutter system of the invention, the shutter and the coating source have a round or oval or rectangular or polygonal shape. It is thus possible to match the shutter to the shape of the coating source to be covered in order to optimally seal it. By virtue of the independently performable movements (rotary and/or pivoting and/or folding or tilting movement, and the additional relative movement) of the shutter, the shutter system of the invention can likewise be matched to any coating source in a very simple manner.

In one configuration of the shutter system of the invention the coating source is a sputtering target.

In another configuration of the shutter system of the invention, the coating source is an electron beam evaporator.

In a further configuration of the shutter system of the invention, the coating source is a boat evaporator and/or a helical evaporator.

In another, further configuration of the shutter system of the invention, the coating source is an effusion cell. An effusion cell is a device for evaporation of the coating source materials in molecular beam epitaxy, or in the production of thin layers in ultrahigh and high vacuum. It consists of a crucible (usually but not necessarily made of pyrolytic boron nitride (PBN)) in which the coating source material is stored in solid form. The crucible is actively heated until the material evaporates, which material is subsequently deposited on the substrate.

This means that the shutter system of the invention can be used for any coating source with a directed stream of particles. Effective prevention of cross-contamination of the coating source and contamination of any substrate to be coated is thus possible in a simple and compact manner.

The object is also achieved by a method of the invention according to independent method claim 10. The method comprises the following steps, wherein the method is executed with the shutter system of the invention according to the assembly claims:

With the coating source switched off, the shutter closes off and seals the coating source. Before the coating source is switched on, by a relative movement of the shutter and the coating source with respect to one another, a distance of 1 to 4 mm between the shutter and the coating source is established. As soon as stable process parameters have become established, the shutter is opened by a rotary and/or pivoting and/or folding or tilting movement. The shutter remains open during the substrate coating and, only after the substrate coating has ended, the shutter is pivoted or moved or folded/tilted over the coating source, and the coating source is closed again in a sealing and gap-free manner by means of a relative movement between coating source and shutter. The actuation of the shutter system of the invention allows the shutter to be kept in any required and desired position.

The invention is to be elucidated in more detail hereinafter by working examples. The accompanying figures show:

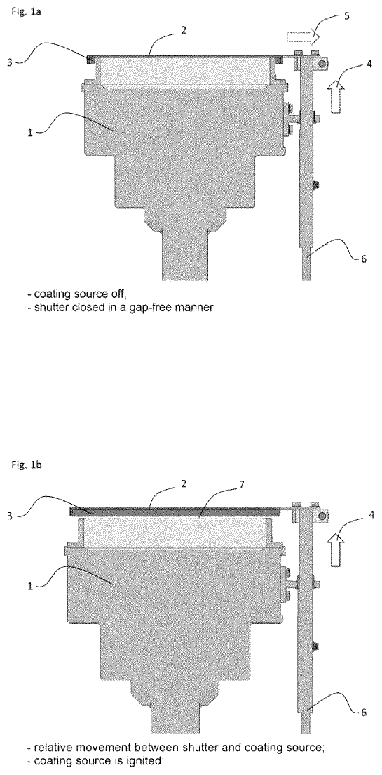

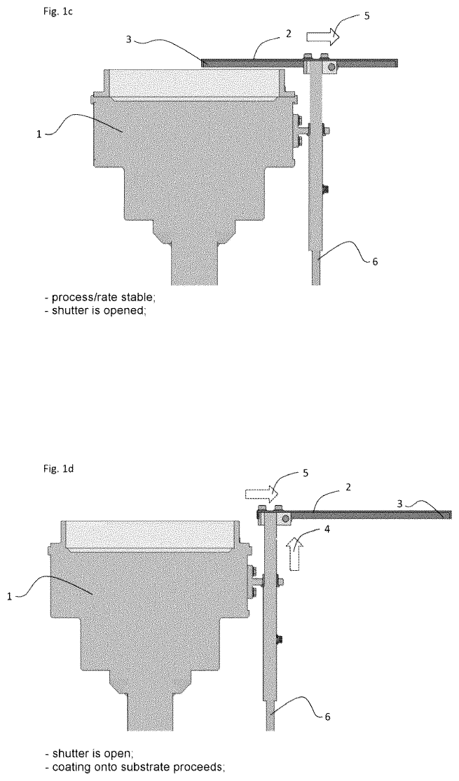

FIG. 1 shutter system of the invention with a coating source (a sputtering target) in a cross-sectional view; the shutter is in various positions over the coating source;

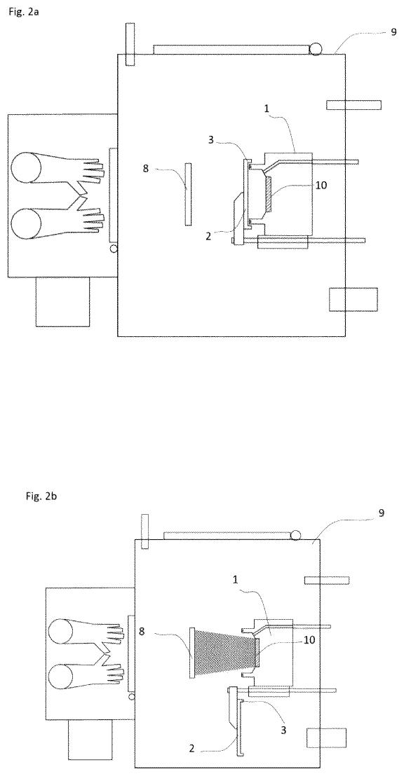

FIG. 2 shutter system of the invention with folded-over edge in a coating system a) with the shutter closed in a gap-free manner, b) with the shutter open.

FIG. 1 shows one embodiment of the shutter system of the invention in an arrangement with a coating source 1 in various positions of the shutter 2 during a coating process. With the coating source 1 switched off, the shutter 2 closes the coating source 1 in a sealing manner. Before the coating source 1 is switched on, especially when igniting the plasma in the sputtering operation, a relative movement 4 of the shutter 2 and the coating source 1 relative to one another establishes a distance 7 of 1 to 4 mm between the shutter 2 and the coating source 1. As soon as stable process parameters have been established, the shutter 2 is completely opened by a rotary and/or pivoting and/or folding or tilting movement 5. The shutter 2 remains open during the substrate coating, and only after the substrate coating has ended is the shutter 2 pivoted or pushed or folded/tilted 5 over the coating source 1 again and the coating source 1 closed again in a sealing and gap-free manner by means of a relative movement 4 between coating source 1 and shutter 2. In other words, either the shutter 2 moves on to the coating source 1 via a linear back-and-forth movement 4 or the coating source 1 is moved toward the shutter 2 via a back-and-forth movement 4.

The advantage of the shutter system of the invention is considered to be that the shutter completely closes off the coating sources 1. No cross-contamination or unwanted parasitic coating on the substrate occurs. The controller of the shutter system is outside the vacuum chamber, such that abrasion by mechanical components within the vacuum chamber is reduced to a minimum.

It is easily possible to retrofit existing systems with the shutter system of the invention in order to be able to make use of the advantages mentioned.

FIG. 2 shows the shutter system of the invention in a process chamber 9. In FIG. 2a, the shutter 2 is positioned above the coating source 1 in a sealing and gap-free manner. No coating material from the sputtering target 10 can get into the process chamber 9 or onto the substrate 8. By virtue of the folded-over edge 3 of the shutter 2, a gap-free assembly which is completely closed off from the process chamber is achievable.

FIG. 2b shows the same arrangement as in FIG. 2a, except that the shutter has been rotated or pivoted or folded/tilted to the side, such that the substrate 8 can now be coated. For the opening of the shutter 2, either the shutter 2 or the coating source 1 performs a linear back-and-forth movement 4, i.e. either the shutter 2 moves away from the coating source 1 or the coating source 1 moves away from the shutter 2, and is subsequently folded/tilted, rotated or pivoted 5 to the side.

### LIST OF REFERENCE NUMERALS

1 coating source
2 shutter
3 folded-over edge
4 relative movement between shutter and coating source, back-and-forth movement
5 rotary and/or pivoting and/or folding/tilting movement
6 ring seal or linear feedthrough or bellows
7 distance between shutter and coating source
8 substrate
9 process chamber
10 target

1. A shutter system consisting of a shutter for shielding a coating source in a vacuum system, where the shutter is designed to be movable in front of the coating source, wherein the shutter is positionable over the coating source by means of a rotary and/or pivoting and/or folding/tilting movement and the shutter is designed to perform an additional relative movement to the coating source and/or the coating source is designed to perform an additional relative movement to the shutter, where the shutter covers the coating source in a sealing and gap-free manner.

2. The shutter system as claimed in claim 1, wherein the relative movement between shutter and coating source is implemented by bellows or ring seals and/or linear feedthroughs.

3. The shutter system as claimed in claim 1, wherein a distance between coating source and shutter is adjustable.

4. The shutter system as claimed in claim 1, wherein the shutter has a folded-over edge.

5. The shutter system as claimed in claim 1, wherein the shutter and the coating source have a round or oval or rectangular or polygonal shape.

6. The shutter system as claimed in claim 1, wherein the coating source is a sputtering target.

7. The shutter system as claimed in claim 1, wherein the coating source is an electron beam evaporator.

8. The shutter system as claimed in claim 1, wherein the coating source is a boat evaporator and/or helical evaporator.

9. The shutter system as claimed in claim 1, wherein the coating source is an effusion cell.

10. A method of shielding a coating source having a shutter system as claimed in claim 1, wherein
with the coating source switched off, the shutter closes off and seals the coating source,
in that, before the coating source is switched on, by a relative movement of the shutter and/or the coating source, a distance of 1 to 4 mm between the shutter and the coating source is established,
in that, as soon as stable process parameters have become established, the shutter is opened,
in that, the shutter remains open during the substrate coating,
in that, after the substrate coating has ended, the shutter is pivoted or moved or folded or tilted over the coating source, and the coating source is closed again in a sealing and gap-free manner by of a relative movement between coating source and shutter.
